(19) United States
(12) Patent Application Publication
(10) Pub. No.: US 2017/0133352 A1
(43) Pub. Date: May 11, 2017

(54) THERMALLY ENHANCED SEMICONDUCTOR ASSEMBLY WITH THREE DIMENSIONAL INTEGRATION AND METHOD OF MAKING THE SAME

(71) Applicant: BRIDGE SEMICONDUCTOR CORPORATION, Taipei (TW)

(72) Inventors: Charles W. C. Lin, Singapore (SG); Chia-Chung Wang, Hsinchu County (TW)

(21) Appl. No.: 15/415,844

(22) Filed: Jan. 25, 2017

Related U.S. Application Data
(63) Continuation-in-part of application No. 15/166,185, filed on May 26, 2016.
Application No. 15/166,185 is a continuation-in-part of application No. 15/289,126, filed on Oct. 8, 2016.
Application No. 15/289,126 is a continuation-in-part of application No. 15/353,537, filed on Nov. 16, 2016.
Application No. 15/289,126 is a continuation-in-part of application No. 15/166,185, filed on May 26, 2016.
Application No. 15/353,537 is a continuation-in-part of application No. 15/166,185, filed on May 26, 2016.
Application No. 15/166,185 is a continuation-in-part of application No. 15/289,126, filed on Oct. 8, 2016.
(60) Provisional application No. 62/166,771, filed on May 27, 2015.

(51) Int. Cl. H01L 25/065; H01L 23/538; H01L 21/48; H01L 25/00; H01L 23/367; H01L 23/31; H01L 23/00; H01L 21/56; H01L 21/683

(52) U.S. Cl. CPC H01L 25/0657; H01L 21/56; H01L 23/5383; H01L 23/5384; H01L 21/4857; H01L 21/6835; H01L 23/5386; H01L 23/5389; H01L 23/3675; H01L 23/3128; H01L 24/17; H01L 25/50; H01L 2224/16057; H01L 2224/16113; H01L 2224/16227; H01L 2924/15153; H01L 2924/19105; H01L 2924/19107; H01L 2221/68345; H01L 2924/15747; H01L 2924/15763; H01L 2924/01022; H01L 2225/06517; H01L 2224/81191; H01L 2224/81203; H01L 2224/81207; H01L 2224/81815; H01L 2221/68381; H01L 2224/81005; H01L 2225/06589; H01L 2225/06586; H01L 2924/15311; H01L 2225/06572; H01L 2224/16055

(57) ABSTRACT

A semiconductor assembly with three dimensional integration includes a face-to-face semiconductor sub-assembly electrically coupled to a heat spreader by bonding wires. The face-to-face semiconductor sub-assembly includes top and bottom devices assembled on opposite sides of a first routing circuitry, and the heat spreader includes a metal plate and a second routing circuitry on the metal plate. The sub-assembly is disposed in a through opening of the second routing circuitry of the heat spreader, and the bonding wires provide electrical connections between the first and second routing circuitries for interconnecting the devices face-to-face assembled in the sub-assembly to terminal pads provided in the heat spreader

### CROSS REFERENCE TO RELATED APPLICATIONS

This application is a continuation-in-part of U.S. application Ser. No. 15/166,185 filed May 26, 2016, a continuation-in-part of U.S. application Ser. No. 15/289,126 filed Oct. 8, 2016 and a continuation-in-part of U.S. application Ser. No. 15/353,537 filed Nov. 16, 2016. The U.S. application Ser. No. 15/166,185 claims the priority benefit of U.S. Provisional Application Ser. No. 62/166,771 filed May 27, 2015. The U.S. application Ser. No. 15/289,126 is a continuation-in-part of U.S. application Ser. No. 15/166,185 filed May 26, 2016. The U.S. application Ser. No. 15/353,537 is a continuation-in-part of U.S. application Ser. No. 15/166,185 filed May 26, 2016 and a continuation-in-part of U.S. application Ser. No. 15/289,126 filed Oct. 8, 2016. The entirety of each of said Applications is incorporated herein by reference.

### FIELD OF THE INVENTION

The present invention relates to a semiconductor assembly and, more particularly, to a thermally enhanced semiconductor assembly with three dimensional integration having a face-to-face semiconductor sub-assembly electrically connected to a heat spreader through bonding wires, and a method of making the same.

### DESCRIPTION OF RELATED ART

Market trends of multimedia devices demand for faster and slimmer designs. One of assembly approaches is to interconnect two devices with “face-to-face” configuration so that the routing distance between the two devices can be the shortest possible. As the stacked devices can talk directly to each other with reduced latency, the assembly's signal integrity and additional power saving capability are greatly improved. As a result, the face-to-face semiconductor assembly offers almost all of the true 3D IC stacking advantages without the need of expensive through-silicon-via (TSV) in the stacked chips. However, as semiconductor devices are susceptible to performance degradation at high operational temperatures, stacking chips with face-to-face configuration without proper heat dissipation would worsen devices' thermal environment and may cause immediate failure during operation.

Additionally, U.S. Pat. Nos. 8,008,121, 8,519,537 and 8,558,395 disclose various assembly structures having an interposer disposed in between the face-to-face chips. Although there is no TSV in the stacked chips, the TSV in the interposer that serves for circuitry routing between chips induces complicated manufacturing processes, high yield loss and excessive cost.

For the reasons stated above, and for other reasons stated below, an urgent need exists to provide a new semiconductor assembly that can address high packaging density, better signal integrity and high thermal dissipation requirements.

### SUMMARY OF THE INVENTION

The objective of the present invention is to provide a semiconductor assembly with three dimensional integration in which a face-to-face semiconductor sub-assembly is thermally and electrically connected to a heat spreader. The heat spreader includes a metal plate and a routing circuitry. The metal plate offers a heat dissipation pathway for the sub-assembly, and the routing circuitry offers electrical fan-out for the sub-assembly through a plurality of bonding wires, thereby effectively improving thermal and electrical performances of the assembly.

In accordance with the foregoing and other objectives, the present invention provides a semiconductor assembly having a face-to-face semiconductor sub-assembly electrically connected to a heat spreader through bonding wires. The face-to-face semiconductor sub-assembly includes a first device, a second device and a first routing circuitry. The heat spreader includes a metal plate and a second routing circuitry. In a preferred embodiment, the first device is thermally conductible to the metal plate and spaced from and face-to-face electrically connected to the second device through the first routing circuitry; the first routing circuitry provides primary fan-out routing and the shortest interconnection distance between the first device and the second device; the second routing circuitry is disposed on the metal plate and laterally surrounds the sub-assembly and provides further fan-out routing; and the bonding wires are attached to the sub-assembly and the heat spreader to electrically connect the first routing circuitry to the second routing circuitry.

In another aspect, the present invention provides a semiconductor assembly, comprising: a face-to-face semiconductor sub-assembly that includes a first device, a second device and a first routing circuitry, wherein the first device is electrically coupled to a first surface of the first routing circuitry and the second device is electrically coupled to a second surface of the first routing circuitry opposite to the first surface; a heat spreader that includes a metal plate and a second routing circuitry disposed over a surface of the metal plate, wherein the second routing circuitry has a through opening and the face-to-face semiconductor sub-assembly is disposed in the through opening, with the first device attached to the heat spreader and the second surface of the first routing circuitry facing in the same direction as an outer surface of the second routing circuitry; and a plurality of bonding wires that electrically couple the face-to-face semiconductor sub-assembly to the heat spreader through the first routing circuitry and the second routing circuitry.

In yet another aspect, the present invention provides a method of making a semiconductor assembly, comprising: providing a face-to-face semiconductor sub-assembly that includes a first device, a second device and a first routing circuitry, wherein the first device is electrically coupled to a first surface of the first routing circuitry and the second device is electrically coupled to a second surface of the first routing circuitry opposite to the first surface; providing a heat spreader that includes a metal plate and a second routing circuitry, wherein the second routing circuitry is disposed over a surface of the metal plate and has a through opening; attaching the face-to-face semiconductor sub-assembly in the through opening of the second routing circuitry; and providing a plurality of bonding wires that electrically couple the face-to-face semiconductor sub-assembly and the heat spreader.

Unless specifically indicated or using the term “then” between steps, or steps necessarily occurring in a certain order, the sequence of the above-mentioned steps is not limited to that set forth above and may be changed or reordered according to desired design.

The semiconductor assembly and the method of making the same according to the present invention have numerous advantages. For instance, face-to-face electrically coupling the first and second devices to both opposite sides of the first routing circuitry can offer the shortest interconnect distance between the first and second devices. Attaching the bonding wires to the sub-assembly and the heat spreader can offer a reliable connecting channel for interconnecting the devices assembled in the sub-assembly to terminal pads provided in the heat spreader.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIG. 1 is a cross-sectional view of the structure with routing traces formed on a sacrificial carrier in accordance with the first embodiment of the present invention;

FIG. 2 is a cross-sectional view of the structure of FIG. 1 further provided with a dielectric layer and via openings in accordance with the first embodiment of the present invention;

FIG. 3 is a cross-sectional view of the structure of FIG. 2 further provided with first conductive traces in accordance with the first embodiment of the present invention;

FIG. 4 is a cross-sectional view of the structure of FIG. 3 further provided with a first device in accordance with the first embodiment of the present invention;

FIG. 5 is a cross-sectional view of the structure of FIG. 4 further provided with a molding compound material in accordance with the first embodiment of the present invention;

FIG. 6 is a cross-sectional view of the structure of FIG. 5 after removal of the sacrificial carrier in accordance with the first embodiment of the present invention;

FIG. 7 is a cross-sectional view of the structure of FIG. 6 further provided with a second device to finish the fabrication of a face-to-face semiconductor sub-assembly in accordance with the first embodiment of the present invention;

FIG. 8 is a cross-sectional view of the structure with a protruded platform and metal posts projecting from a metal plate in accordance with the first embodiment of the present invention;

FIG. 9 is a cross-sectional view of the structure of FIG. 8 further provided with a binding film and a routing substrate in accordance with the first embodiment of the present invention;

FIG. 10 is a cross-sectional view of the structure of FIG. 9 further subjected to a lamination process in accordance with the first embodiment of the present invention;

FIG. 11 is a cross-sectional view of the structure of FIG. 10 further formed with a cavity to finish the fabrication of a heat spreader in accordance with the first embodiment of the present invention;

FIG. 12 is a cross-sectional view of the structure of FIG. 11 further provided with the face-to-face semiconductor sub-assembly of FIG. 7 in accordance with the first embodiment of the present invention;

FIG. 13 is a cross-sectional view of the structure of FIG. 12 further provided with bonding wires to finish the fabrication of a semiconductor assembly in accordance with the first embodiment of the present invention;

FIG. 14 is a cross-sectional view of the structure of FIG. 13 further provided with an encapsulant in accordance with the first embodiment of the present invention;

FIG. 15 is a cross-sectional view of the structure of FIG. 14 further provided with solder balls in accordance with the first embodiment of the present invention;

FIG. 16 is a cross-sectional view of another aspect of the semiconductor assembly in accordance with the first embodiment of the present invention;

FIG. 17 is a cross-sectional view of yet another aspect of the semiconductor assembly in accordance with the first embodiment of the present invention;

FIG. 18 is a cross-sectional view of a heat spreader in accordance with the second embodiment of the present invention;

FIG. 19 is a cross-sectional view of the structure of FIG. 18 further provided with a face-to-face semiconductor sub-assembly in accordance with the second embodiment of the present invention;

FIG. 20 is a cross-sectional view of the structure of FIG. 19 further provided with bonding wires to finish the fabrication of a semiconductor assembly in accordance with the second embodiment of the present invention;

FIG. 21 is a cross-sectional view of the structure of FIG. 20 further provided with an encapsulant in accordance with the second embodiment of the present invention;

FIG. 22 is a cross-sectional view of the structure of FIG. 21 further provided with solder balls in accordance with the second embodiment of the present invention;

FIG. 23 is a cross-sectional view of another aspect of the semiconductor assembly in accordance with the second embodiment of the present invention;

FIG. 24 is a cross-sectional view of the structure with a face-to-face semiconductor sub-assembly and a heat spreader attached on a carrier film in accordance with the third embodiment of the present invention;

FIG. 25 is a cross-sectional view of the structure of FIG. 24 further provided with bonding wires in accordance with the third embodiment of the present invention;

FIG. 26 is a cross-sectional view of the structure of FIG. 25 further provided with an encapsulant in accordance with the third embodiment of the present invention;

FIG. 27 is a cross-sectional view of the structure of FIG. 26 after removal of the carrier film to finish the fabrication of a semiconductor assembly in accordance with the third embodiment of the present invention;

FIG. 28 is a cross-sectional view of the structure of FIG. 27 further provided with a thermally conductive plate in accordance with the third embodiment of the present invention; and

FIG. 29 is a cross-sectional view of the structure of FIG. 28 further provided with solder balls in accordance with the third embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

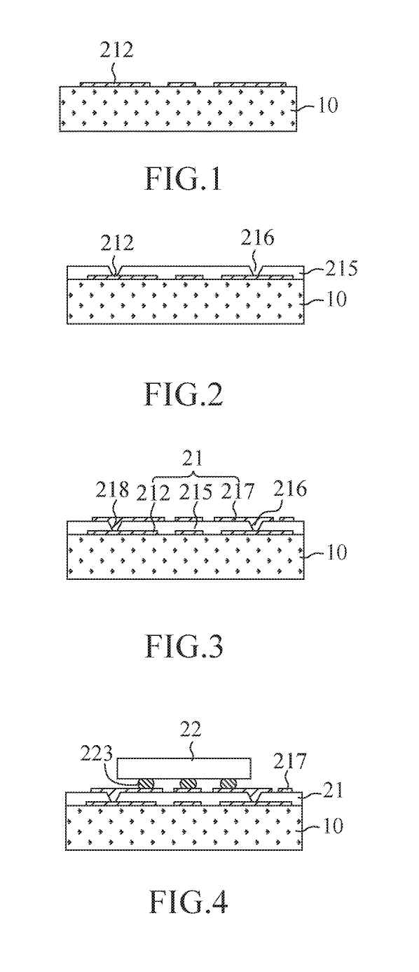

FIGS. 1-13 are schematic views showing a method of making a semiconductor assembly that includes a first routing circuitry 21, a first device 22, a molding compound material 25, a second device 27, a heat spreader 30 and bonding wires 41, 43 in accordance with the first embodiment of the present invention.

FIG. 1 is a cross-sectional view of the structure with routing traces 212 formed on a sacrificial carrier 10. The sacrificial carrier 10 typically is made of copper, aluminum, iron, nickel, tin, stainless steel, silicon, or other metals or alloys, but any other conductive or non-conductive material also may be used. In this embodiment, the sacrificial carrier 10 is made of an iron-based material. The routing traces 212 typically are made of copper and can be pattern deposited by numerous techniques, such as electroplating, electroless plating, evaporating, sputtering or their combinations, or be thin-film deposited followed by a metal patterning process. For a conductive sacrificial carrier 10, the routing traces 212 are deposited typically by plating of metal. The metal patterning techniques include wet etching, electro-chemical etching, laser-assist etching, and their combinations with an etch mask (not shown) thereon that defines the routing traces 212.

FIG. 2 is a cross-sectional view of the structure with a dielectric layer 215 on the sacrificial carrier 10 as well as the routing traces 212 and via openings 216 in the dielectric layer 215. The dielectric layer 215 is deposited typically by lamination or coating, and contacts and covers and extends laterally on the sacrificial carrier 10 and the routing traces 212 from above. The dielectric layer 215 typically has a thickness of 50 microns, and can be made of epoxy resin, glass-epoxy, polyimide, or the like. After the deposition of the dielectric layer 215, the via openings 216 are formed by numerous techniques, such as laser drilling, plasma etching and photolithography, and typically have a diameter of 50 microns. Laser drilling can be enhanced by a pulsed laser. Alternatively, a scanning laser beam with a metal mask can be used. The via openings 216 extend through the dielectric layer 215 and are aligned with selected portions of the routing traces 212.

Referring now to FIG. 3, first conductive traces 217 are formed on the dielectric layer 215 by metal deposition and metal patterning process. The first conductive traces 217 extend from the routing traces 212 in the upward direction, fill up the via openings 216 to form metallized vias 218 in direct contact with the routing traces 212, and extend laterally on the dielectric layer 215. As a result, the first conductive traces 217 can provide horizontal signal routing in both the X and Y directions and vertical routing through the via openings 216 and serve as electrical connections for the routing traces 212.

The first conductive traces 217 can be deposited as a single layer or multiple layers by any of numerous techniques, such as electroplating, electroless plating, evaporating, sputtering, or their combinations. For instance, they can be deposited by first dipping the structure in an activator solution to render the dielectric layer 215 catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, the plated layer can be patterned to form the first conductive traces 217 by any of numerous techniques such as wet etching, electro-chemical etching, laser-assist etching, or their combinations, with an etch mask (not shown) thereon that defines the first conductive traces 217.

At this stage, the formation of a first routing circuitry 21 on the sacrificial carrier 10 is accomplished. In this illustration, the first routing circuitry 21 is a multi-layered buildup circuitry and includes routing traces 212, a dielectric layer 215 and first conductive traces 217.

FIG. 4 is a cross-sectional view of the structure with a first device 22 electrically coupled to the first routing circuitry 21. The first device 22 can be electrically coupled to the first conductive traces 217 of the first routing circuitry 21 using first bumps 223 in contact with the first device 22 and the first routing circuitry 21 by thermal compression, solder reflow or thermosonic bonding. In this example, the first device 22 is illustrated as a semiconductor chip.

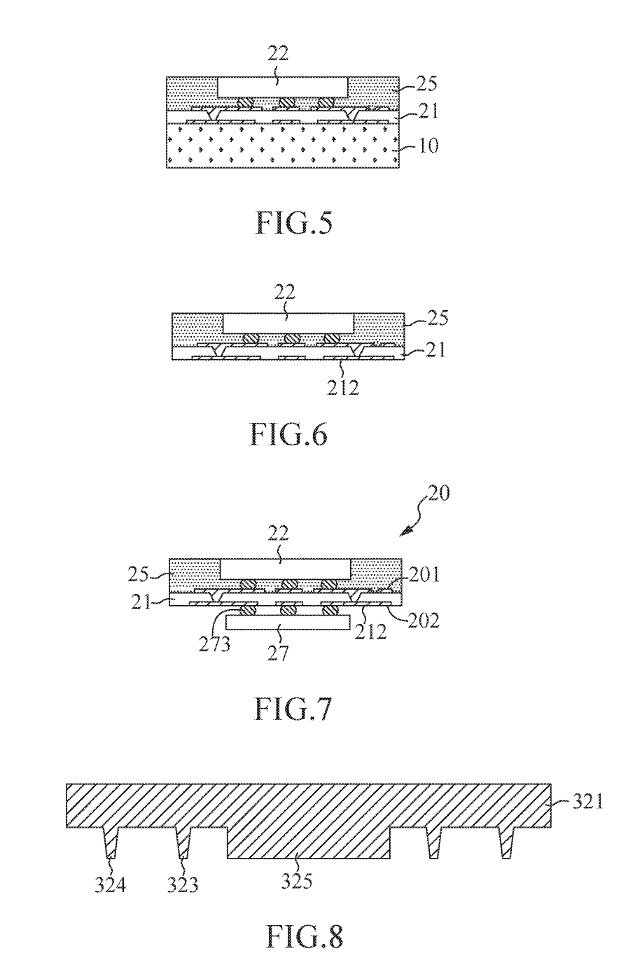

FIG. 5 is a cross-sectional view of the structure with a molding compound material 25 on the first routing circuitry 21 and around the first device 22 by, for example, resin-glass lamination, resin-glass coating or molding. The molding compound material 25 covers the first routing circuitry 21 from above and surrounds and conformally coats and covers sidewalls of the first device 22. As an alternative, the step of providing the molding compound material 25 may be omitted.

FIG. 6 is a cross-sectional view of the structure after removal of the sacrificial carrier 10. The sacrificial carrier 10 can be removed to expose the first routing circuitry 21 from below by numerous techniques, such as wet chemical etching using acidic solution (e.g., ferric chloride, copper sulfate solutions), or alkaline solution (e.g., ammonia solution), electro-chemical etching, or mechanical process such as a drill or end mill followed by chemical etching. In this embodiment, the sacrificial carrier 10 made of an iron-based material is removed by a chemical etching solution that is selective between copper and iron so as to prevent the copper routing traces 212 from being etched during removal of the sacrificial carrier 10.

FIG. 7 is a cross-sectional view of the structure with a second device 27 electrically coupled to the first routing circuitry 21. The second device 27 can be electrically coupled to the routing traces 212 of the first routing circuitry 21 using second bumps 273 in contact with the second device 27 and the first routing circuitry 21 by thermal compression, solder reflow or thermosonic bonding. In this example, the second device 27 is illustrated as a semiconductor chip. However, in some cases, the second device 27 may be a packaged device or a passive component.

At this stage, a face-to-face semiconductor sub-assembly 20 is accomplished and includes a first routing circuitry 21, a first device 22, a molding compound material 25, and a second device 27. The first device 22 and the second device 27 are electrically coupled to first and second surfaces 201, 202 of the first routing circuitry 21, respectively, and the molding compound material 25 is disposed over the first surface 201 and around the first device 22.

FIG. 8 is a cross-sectional view of the structure having a metal plate 321, metal posts 323, 324 and a protruded platform 325. The metal plate 321, the metal posts 323, 324 and the protruded platform 325 typically are integrated as one piece and can be made of copper, aluminum, stainless steel, or other metals or alloys. In this embodiment, the metal plate 321, the metal posts 323, 324 and the protruded platform 325 are made of copper. The metal posts 323, 324 and the protruded platform 325 project from a surface of the metal plate 321 and typically are formed by photolithography and wet etching.

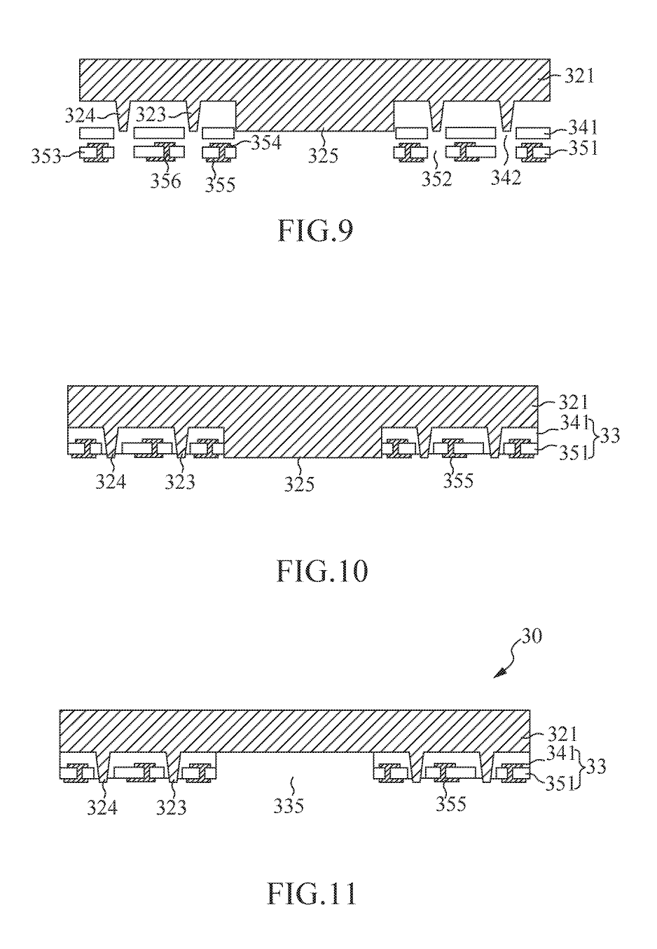

FIGS. 9-10 are cross-sectional views showing a process of laminating a routing substrate 351 on the metal plate 321 using a binding film 341. The lamination process is executed by inserting the metal posts 323, 324 and the protruded platform 325 into apertures 352 of the routing substrate 351 as well as openings 342 of the binding film 341. The openings 342 and the apertures 352 typically are formed by laser cutting through the binding film 341 and the routing substrate 351, respectively, and also may be formed by other techniques such as punching or mechanical drilling. The binding film 314 can be various dielectric films or prepregs formed from numerous organic or inorganic electrical insulators. In this illustration, the routing substrate 351 is a laminate that includes an insulating layer 353, second conductive traces 354, third conductive traces 355, and metallized through vias 356. The insulating layer 353 typically has a thickness of 50 microns, and can be made of epoxy resin, glass-epoxy, polyimide, or the like. The second conductive traces 354 and the third conductive traces 355 are disposed on opposite sides of the insulating layer 353. The metallized through vias 356 extend through the insulating layer 353 and are electrically coupled to the second conductive traces 354 and the third conductive traces 355.

Under heat and pressure, the binding film 341 between the metal plate 321 and the routing substrate 351 is melted and forced into gaps between the metal posts 323, 324 and the routing substrate 351. As a result, the metal plate 321 and the metal posts 323, 324 are spaced from the routing substrate 351 by the binding film 341. The binding film 341 when solidified provides secure robust mechanical bonds between the metal plate 321 and the routing substrate 351 and between the metal posts 323, 324 and the routing substrate 351.

At this stage, the formation of a second routing circuitry 33 on the metal plate 321 is accomplished, and includes a binding film 341 and a routing substrate 351. In this illustration, the metal posts 323, 324 and the protruded platform 325 extend through the second routing circuitry 33, and each has an exposed surface substantially coplanar with the exterior surface of the third conductive traces 355 of the routing substrate 351 in the downward direction.

FIG. 11 is a cross-sectional view of the structure with a selected portion of the metal plate 321 exposed from below by removing the protruded platform 325. The protruded platform 325 can be removed to expose the selected portion of the metal plate 321 from a through opening 335 of the second routing circuitry 33 by numerous techniques, such as wet chemical etching using acidic solution (e.g., ferric chloride, copper sulfate solutions), or alkaline solution (e.g., ammonia solution), electro-chemical etching, or mechanical process such as a drill or end mill followed by chemical etching.

At this stage, a heat spreader 30 is accomplished and includes a metal plate 321, an array of metal posts 323, 324 and a second routing circuitry 33. In this illustration, the metal plate 321 is partially exposed from the through opening 335 of the second routing circuitry 33, and the metal posts 323, 324 are laterally surrounded by the second routing circuitry 33.

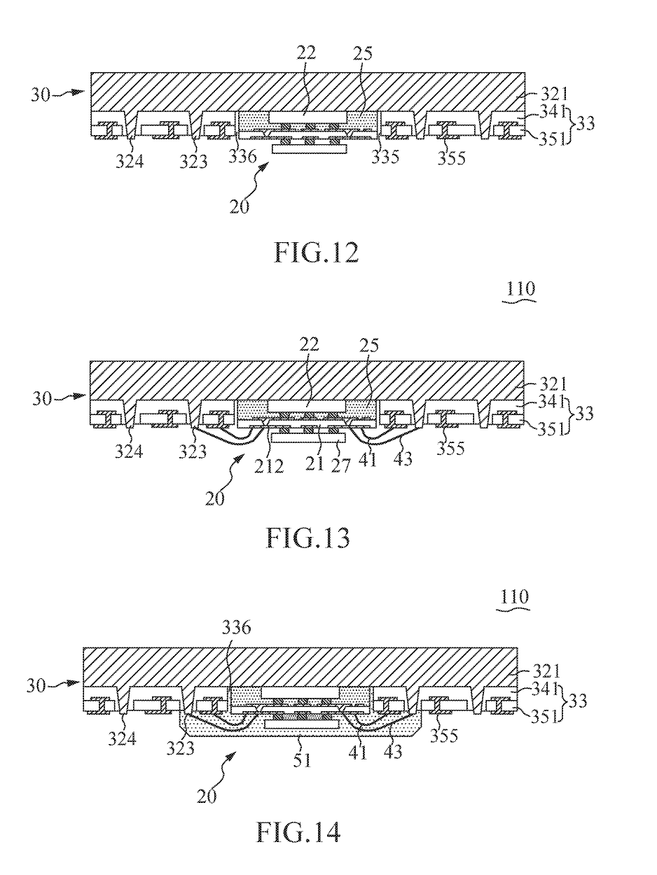

FIG. 12 is a cross-sectional view of the structure with the face-to-face semiconductor sub-assembly 20 of FIG. 7 attached to the heat spreader 30 of FIG. 11. The face-to-face semiconductor sub-assembly 20 is aligned with and disposed in the through opening 335 of the second routing circuitry 33, with the first device 22 attached to the metal plate 321 of the heat spreader 30. The interior sidewalls of the through opening 335 laterally surround and are spaced from peripheral edges of the face-to-face semiconductor sub-assembly 20. As a result, a gap 336 is left in the through opening 335 between the peripheral edges of the face-to-face semiconductor sub-assembly 20 and the interior sidewalls of the second routing circuitry 33. The gap 336 laterally surrounds the face-to-face semiconductor sub-assembly 20 and is laterally surrounded by the second routing circuitry 33.

FIG. 13 is a cross-sectional view of the structure with bonding wires 41, 43 attached to the face-to-face semiconductor sub-assembly 20 and the heat spreader 30 typically by gold or copper ball bonding, or gold or aluminum wedge bonding. The bonding wires 41 contact and are electrically coupled to the routing traces 212 of the first routing circuitry 21 and the third conductive traces 355 of the second routing circuitry 33. The bonding wires 43 contact and are electrically coupled to the routing traces 212 of the first routing circuitry 21 and the metal posts 323. As a result, the bonding wires 41 can electrically couple the first routing circuitry 21 to the second routing circuitry 33 for signal routing, whereas the bonding wires 43 can electrically couple the first routing circuitry 21 to the metal posts 323 for ground connection.

Accordingly, as shown in FIG. 13, a semiconductor assembly 110 is accomplished and includes a face-to-face semiconductor sub-assembly 20 electrically connected to a heat spreader 30 by bonding wires 41, 43. In this illustration, the face-to-face semiconductor sub-assembly 20 includes a first routing circuitry 21, a first device 22, a molding compound material 25 and a second device 27, whereas the heat spreader 30 includes a metal plate 321, metal posts 323, 324 and a second routing circuitry 33.

The first device 22 is flip-chip electrically coupled to the first routing circuitry 21 from one side of the first routing circuitry 21 and enclosed by the molding compound material 25 and the metal plate 321. The second device 27 is flip-chip electrically coupled to the first routing circuitry 21 from the other side of the first routing circuitry 21 and face-to-face connected to the first device 22 through the first routing circuitry 21. As such, the first routing circuitry 21 offers primary fan-out routing and the shortest interconnection distance between the first device 22 and the second device 27. The metal plate 321 of the heat spreader 30 is thermally conductible to and covers the first device 22 from above. The meal posts 323, 324 project from a surface of the metal plate 321 and extend through the second routing circuitry 33. The second routing circuitry 33 is disposed on the surface of the metal plate 321 and electrically coupled to the first routing circuitry 21 by the bonding wires 41 in contact with the second routing circuitry 33 and the first routing circuitry 21. For ground connection, the metal plate 321 and the metal posts 323, 324 are electrically connected to the first routing circuitry 21 by the bonding wires 43 in contact with the metal posts 323 and the first routing circuitry 21. As a result, the metal plate 321 not only provides thermal dissipation for the first device 22, but also offers effective EMI (electromagnetic interference) shielding for the first device 22.

FIG. 14 is a cross-sectional view of the semiconductor assembly 110 further provided with an encapsulant 51. The encapsulant 51 covers the bonding wires 41, 43 and the face-to-face semiconductor sub-assembly 20 as well as selected portions of the heat spreader 30 from below, and further fills up the gaps 336 between the peripheral edges of the face-to-face semiconductor sub-assembly 20 and the interior sidewalls of the heat spreader 30.

FIG. 15 is a cross-sectional view of the semiconductor assembly 110 further provided with solder balls 61. The solder balls 61 are mounted on the second routing circuitry 33 and the metal posts 324 for external connection.

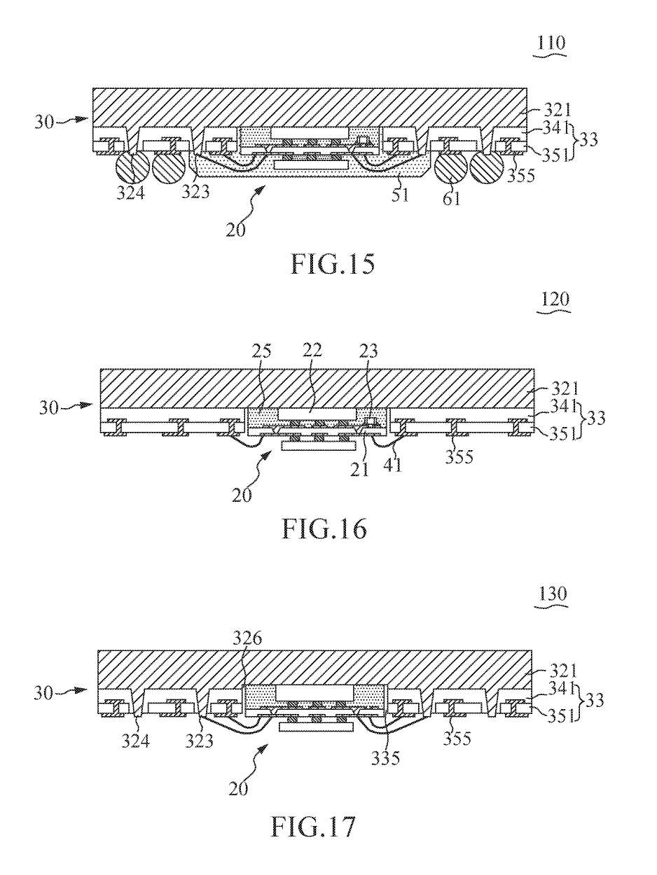

FIG. 16 is a cross-sectional view of another aspect of the semiconductor assembly according to the first embodiment of the present invention. The semiconductor assembly 120 is similar to that illustrated in FIG. 13, except that the face-to-face semiconductor sub-assembly 20 further includes a passive component 23 electrically coupled to the first routing circuitry 21, and the heat spreader 30 includes no metal posts projecting from the metal plate 321.

FIG. 17 is a cross-sectional view of yet another aspect of the semiconductor assembly according to the first embodiment of the present invention. The semiconductor assembly 130 is similar to that illustrated in FIG. 13, except that the metal plate 321 has a recess 326 aligned with the through opening 335 of the second routing circuitry 33, and the face-to-face semiconductor sub-assembly 20 further extends into the recess 326 of the metal plate 321.

### Embodiment 2

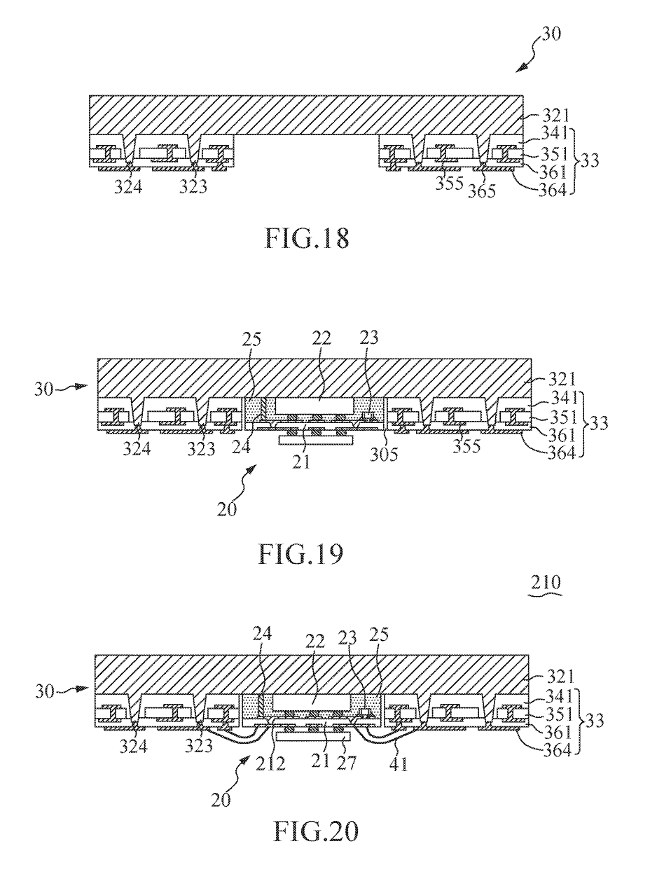

FIGS. 18-20 are schematic views showing a method of making a semiconductor assembly with the second routing circuitry electrically coupled to the metal posts in accordance with the second embodiment of the present invention.

For purposes of brevity, any description in Embodiment 1 above is incorporated herein insofar as the same is applicable, and the same description need not be repeated.

FIG. 18 is a cross-sectional view of a heat spreader 30. The heat spreader 30 is similar to that illustrated in FIG. 11, except that the second routing circuitry 33 further includes a buildup insulating layer 361 laminated/coated on the routing substrate 351 and the metal posts 323, 324, and fourth conductive traces 364 deposited on the buildup insulating layer 361. The buildup insulating layer 361 contacts and covers and extends laterally on the routing substrate 351 and the metal posts 323, 324 from below. The buildup insulating layer 361 typically has a thickness of 50 microns, and can be made of epoxy resin, glass-epoxy, polyimide, or the like. The fourth conductive traces 364 is deposited on the buildup insulating layer 361 by metal deposition and metal patterning process, and includes metallized vias 365 that contact the third conductive traces 355 of the routing substrate 351 and the metal posts 323, 324 and extend through the buildup insulating layer 361.

FIG. 19 is a cross-sectional view of the structure with a face-to-face semiconductor sub-assembly 20 attached to the heat spreader 30 of FIG. 18. The face-to-face semiconductor sub-assembly 20 is disposed in the cavity 305 of the heat spreader 30 and attached to the metal plate 321 of the heat spreader 30. In this illustration, the face-to-face semiconductor sub-assembly 20 is similar to that illustrated in FIG. 7, except that it further includes a passive component 23 and a metal pillar 24 electrically coupled to the first routing circuitry 21 and encapsulated in the molding compound material 25.

FIG. 20 is a cross-sectional view of the structure with bonding wires 41 attached to the face-to-face semiconductor sub-assembly 20 and the heat spreader 30. The bonding wires 41 contact and are electrically coupled to the routing traces 212 of the first routing circuitry 21 and the fourth conductive traces 364 of the second routing circuitry 33.

Accordingly, as shown in FIG. 20, a semiconductor assembly 210 is accomplished and includes a face-to-face semiconductor sub-assembly 20 electrically connected to a heat spreader 30 by bonding wires 41. In this illustration, the face-to-face semiconductor sub-assembly 20 includes a first routing circuitry 21, a first device 22, a passive component 23, a metal pillar 24, a molding compound material 25 and a second device 27, whereas the heat spreader 30 includes a metal plate 321, metal posts 323, 324 and a second routing circuitry 33.

The first device 22/passive component 23 and the second device 27 are disposed at two opposite sides of the first routing circuitry 21 and face-to-face electrically connected to each other through the first routing circuitry 21 therebetween. As such, the first routing circuitry 21 offers the shortest interconnection distance between the first device 22/passive component 23 and the second device 27, and provides first level fan-out routing for the first device 22/passive component 23 and the second device 27. The metal pillar 24 is electrically coupled to the first routing circuitry 21 and extends through the molding compound material 25. The metal plate 321 is electrically connected to the metal pillar 24 for ground connection and thermally conductible to the first device 22 for heat dissipation. The metal posts 323, 324 project from the metal plate 321 and electrically coupled to the second routing circuitry 33 on the metal plate 321 for ground connection. The second routing circuitry 33 is electrically coupled to the first routing circuitry 21 using the bonding wires 41, and provides second level fan-out routing for the first routing circuitry 21.

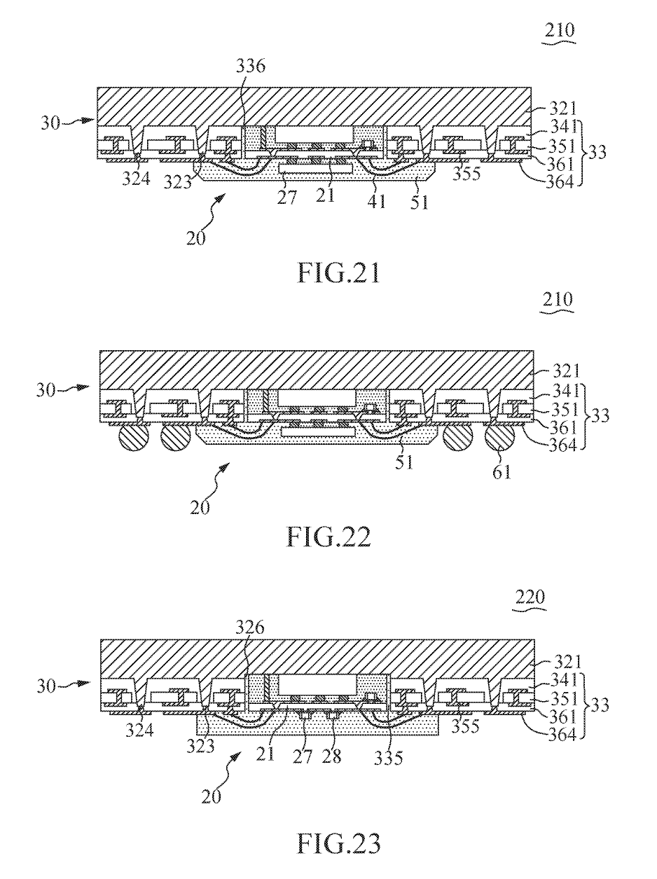

FIG. 21 is a cross-sectional view of the semiconductor assembly 210 further provided with an encapsulant 51. The encapsulant 51 covers the bonding wires 41, the second device 27 and the first routing circuitry 21 as well as selected portions of the second routing circuitry 33 from below, and further fills up the gaps 336 between the peripheral edges of the face-to-face semiconductor sub-assembly 20 and the interior sidewalls of the heat spreader 30.

FIG. 22 is a cross-sectional view of the semiconductor assembly 210 further provided with solder balls 61. The solder balls 61 are mounted on the second routing circuitry 33 for external connection.

FIG. 23 is a cross-sectional view of another aspect of the semiconductor assembly according to the second embodiment of the present invention. The semiconductor assembly 220 is similar to that illustrated in FIG. 21, except that the metal plate 321 has a recess 326 aligned with the through opening 335 of the second routing circuitry 33, and the face-to-face semiconductor sub-assembly 20 further extends into the recess 326 of the metal plate 321 and includes a plurality of second devices 27, 28, illustrated as passive components, electrically coupled to the first routing circuitry 21.

### Embodiment 3

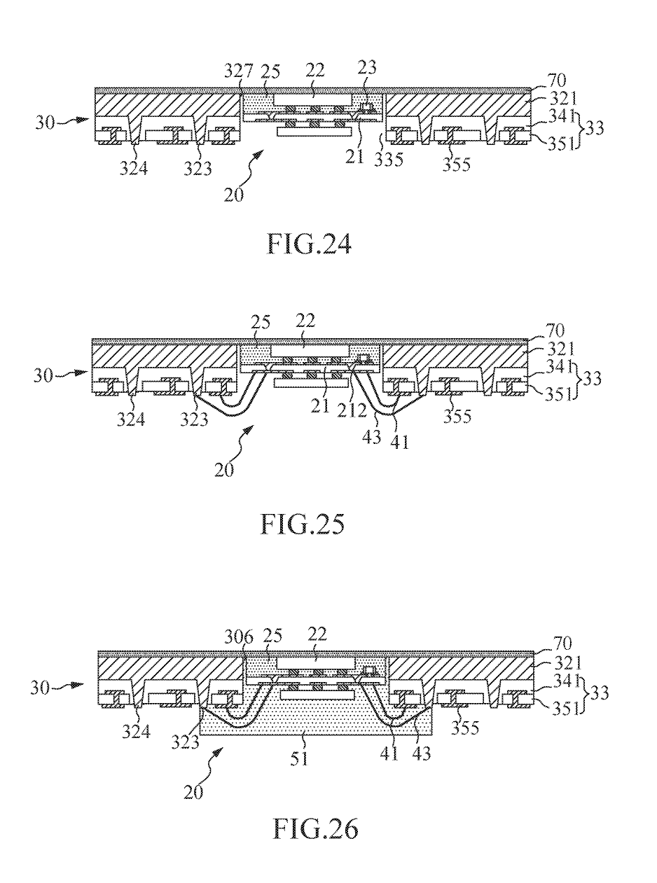

FIGS. 24-27 are schematic views showing a method of making a semiconductor assembly in which the metal plate has an aperture aligned with the through opening of the second routing circuitry in accordance with the third embodiment of the present invention.

For purposes of brevity, any description in Embodiments above is incorporated herein insofar as the same is applicable, and the same description need not be repeated.

FIG. 24 is a cross-sectional view of the structure with a face-to-face semiconductor subassembly 20 and a heat spreader 30 attached to a carrier film 70. The face-to-face semiconductor sub-assembly 20 is similar to that illustrated in FIG. 7, except that it further includes a passive component 23 electrically coupled to the first routing circuitry 21 and encapsulated in the molding compound material 25. The heat spreader 30 is similar to that illustrated in FIG. 11, except that the metal plate 321 of the heat spreader 30 has an aperture 327 aligned with the through opening 335 of the second routing circuitry 33. The carrier film 70 typically is a tape, and can provide temporary retention force for the face-to-face semiconductor sub-assembly 20 steadily residing within the through opening 335 of the second routing circuitry 33 as well as the aperture 327 of the metal plate 321. In this illustration, the face-to-face semiconductor sub-assembly 20 and the heat spreader 30 are attached to the carrier film 70 by the adhesive property of the carrier film 70, with the first device 22, the molding compound material 25 and the metal plate 321 in contact with the carrier film 70. Alternatively, the face-to-face semiconductor sub-assembly 20 and the heat spreader 30 may be attached to the carrier film 70 by dispensing extra adhesive.

FIG. 25 is a cross-sectional view of the structure with bonding wires 41, 43 attached to the face-to-face semiconductor sub-assembly 20 and the heat spreader 30. The bonding wires 41 contact and are electrically coupled to the routing traces 212 of the first routing circuitry 21 and the third conductive traces 355 of the second routing circuitry 33. The bonding wires 43 contact and are electrically coupled to the routing traces 212 of the first routing circuitry 21 and the metal posts 323.

FIG. 26 is a cross-sectional view of the structure provided with an encapsulant 51. The encapsulant 51 covers the bonding wires 41, 43 and the face-to-face semiconductor sub-assembly 20 as well as selected portions of the heat spreader 30 from below. Additionally, the encapsulant 51 further fills up gaps 306 between the peripheral edges of the face-to-face semiconductor sub-assembly 20 and the interior sidewalls of the heat spreader 30. As a result, the encapsulant 51 can provide secure robust mechanical bonds to attach the peripheral edges of the face-to-face semiconductor sub-assembly 20 to the interior sidewalls of the heat spreader 30. Alternatively, the peripheral edges of the face-to-face semiconductor sub-assembly 20 may be attached to the interior sidewalls of the heat spreader 30 by dispensing extra adhesive in the gasp 306 before provision of the bonding wires 41, 43 and the encapsulant 51.

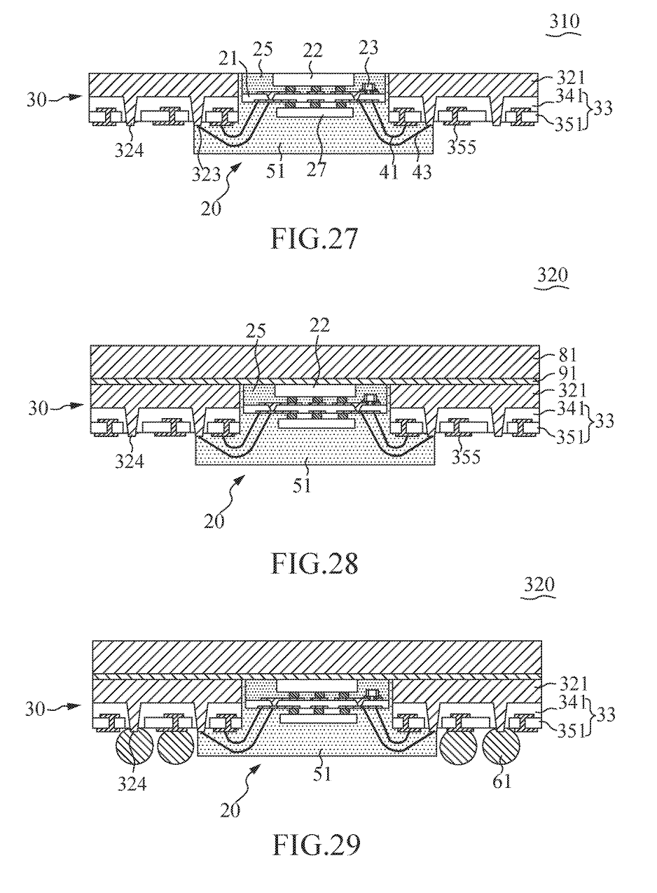

FIG. 27 is a cross-sectional view of the structure after removal of the carrier film 70. The carrier film 70 is detached from the face-to-face semiconductor sub-assembly 20 and the heat spreader 30 to expose the first device 22 and the metal plate 321 from above. Accordingly, a semiconductor assembly 310 is accomplished and includes a face-to-face semiconductor sub-assembly 20, a heat spreader 30, bonding wires 41, 43, and an encapsulant 51. In this illustration, the face-to-face semiconductor sub-assembly 20 includes a first routing circuitry 21, a first device 22, a passive component 23, a molding compound material 25 and a second device 27, whereas the heat spreader 30 includes a metal plate 321, metal posts 323, 324 and a second routing circuitry 33.

FIG. 28 is a cross-sectional view of another aspect of the semiconductor assembly according to the third embodiment of the present invention. For effective heat dissipation, a thermally conductive plate 81 may be further attached on the first device 22 and the molding compound material 25 of the face-to-face semiconductor sub-assembly 20 and the metal plate 321 of the heat spreader 30 typically by a thermally conductive adhesive 91. The thermally conductive plate 81 can be made of any material with high thermal conductivity, such as copper, aluminum, stainless steel, silicon, ceramic, graphite or other metals or alloys. As a result, the heat generated by the first device 22 can be conducted away through the thermally conductive plate 81.

FIG. 29 is a cross-sectional view of the semiconductor assembly 320 further provided with solder balls 61. The solder balls 61 are mounted on the second routing circuitry 33 and the metal posts 324 for external connection.

The semiconductor assemblies described above are merely exemplary. Numerous other embodiments are contemplated. In addition, the embodiments described above can be mixed-and-matched with one another and with other embodiments depending on design and reliability considerations. For instance, the second routing circuitry may have multiple through openings in an array and each face-to-face semiconductor sub-assembly is accommodated in its corresponding through opening. Also, the second routing circuitry of the heat spreader can include additional conductive traces to receive and route additional face-to-face semiconductor sub-assemblies.

As illustrated in the aforementioned embodiments, a distinctive semiconductor assembly is configured and includes a face-to-face semiconductor sub-assembly electrically coupled to a heat spreader by bonding wires. Optionally, an encapsulant may be further provided to cover the bonding wires. For the convenience of below description, the direction in which the first surface of the first routing circuitry faces is defined as the first direction, and the direction in which the second surface of the first routing circuitry faces is defined as the second direction.

The face-to-face semiconductor sub-assembly includes a first device, a second device, a first routing circuitry and optionally a molding compound material, and may be prepared by the steps of: electrically coupling the first device to the first surface of the first routing circuitry detachably adhered over a sacrificial carrier; optionally providing the molding compound material over the first routing circuitry and around the first device; removing the sacrificial carrier from the first routing circuitry; and electrically coupling the second device to the second surface of the first routing circuitry. As a result, the first and second devices, respectively disposed over the first and second surfaces of the first routing circuitry, can be electrically connected to each other by the first routing circuitry.

The first device can be a semiconductor chip, and the second device can be a semiconductor chip, a packaged device, or a passive component. The first device can be electrically coupled to the first routing circuitry by a well-known flip chip bonding process with its active surface facing in the first routing circuitry using bumps without metallized vias in contact with the first device. Likewise, after removal of the sacrificial carrier, the second device can be electrically coupled to the first routing circuitry by a well-known flip chip bonding process with its active surface facing in the first routing circuitry using bumps without metallized vias in contact with the second device.

The first routing circuitry can be a buildup circuitry without a core layer to provide primary fan-out routing/interconnection and the shortest interconnection distance between the first and second devices. Preferably, the first routing circuitry is a multi-layered buildup circuitry and can include at least one dielectric layer and conductive traces that fill up via openings in the dielectric layer and extend laterally on the dielectric layer. The dielectric layer and the conductive traces are serially formed in an alternate fashion and can be in repetition when needed. Accordingly, the first routing circuitry can be formed with electrical contacts at its first and second surfaces for first device connection from the first surface and second device connection and next-level connection from the second surface.

The heat spreader includes a metal plate, a second routing circuitry on a surface of the metal plate, and one or more optional metal posts projecting from the surface of the metal plate and laterally surrounded by the second routing circuitry. Preferably, the metal plate and the optional metal posts are integrated as one piece. In accordance with one aspect of the present invention, the face-to-face semiconductor sub-assembly is accommodated in a through opening of the second routing circuitry leaving gaps between the peripheral edges of the face-to-face semiconductor sub-assembly and the interior sidewalls of the through opening, and is attached to the surface of the metal plate. Alternatively, the metal plate may have a recess aligned with the through opening of the second routing circuitry, and the face-to-face semiconductor sub-assembly disposed in the through opening is also further inserted into the recess of the metal plate and attached to the metal plate. Accordingly, the first device is thermally conductible to the metal plate of the heat spreader, and the peripheral edges of the dielectric layer(s) of the first routing circuitry is laterally surrounded by interior sidewalls of the heat spreader. As an alternative aspect of the present invention, the metal plate may have an aperture aligned with the through opening and extending through the metal plate, and a carrier film (typically an adhesive tape) may be used to provide temporary retention force for the face-to-face semiconductor sub-assembly and the heat spreader. For instance, the carrier film can temporally adhere to the face-to-face semiconductor sub-assembly and the metal plate of the heat spreader to retain the face-to-face semiconductor sub-assembly in the through opening of the second routing circuitry as well as the aperture of the metal plate. After an encapsulant is provided to cover the bonding wires and further fill up gaps between the peripheral edges of the sub-assembly and the interior sidewalls of the through opening and the aperture, the carrier film can be detached therefrom. Alternatively, an adhesive may be dispensed in gaps between the peripheral edges of the sub-assembly and the interior sidewalls of the through opening and the aperture before detaching the carrier film. Accordingly, the adhesive or the encapsulant can provide secure robust mechanical bonds to attach the peripheral edges of the face-to-face semiconductor sub-assembly to the interior sidewalls of the heat spreader. Further, in the alternative aspect of the metal plate having the aperture, a thermally conductive plate may be attached to the metal plate of the heat spreader and the sub-assembly accommodated in the aperture and the through opening of the heat spreader. As a result, the thermally conductive plate can provide thermal dissipation for the first device attached thereto.

The second routing circuitry may be a multi-layered routing circuitry that includes at least one insulating layer and conductive traces. The insulating layer and the conductive traces are serially formed in an alternate fashion and can be in repetition when needed. In a preferred embodiment, the second routing circuitry includes a binding film and a routing substrate. The routing substrate preferably include an insulating layer, conductive traces on both opposite sides of the insulating layer, and metallized through vias extending through the insulating layer to provide electrical connections between the conductive traces. By the binding film, the routing substrate can be bonded to the metal plate and the optional metal posts of the heat spreader. More specifically, the optional metal posts of the heat spreader are disposed within apertures of the routing substrate, and the binding film between the metal plate and the routing substrate is forced into and fills up gaps in the apertures between the optional metal posts and the routing substrate. As a result, the binding film can provide robust mechanical bonds between the metal plate and the routing substrate and between the optional metal posts and the routing substrate. Optionally, the second routing circuitry may further include at least one buildup insulating layer and additional conductive traces that fill up via openings in the buildup insulating layer and extend laterally on the buildup insulating layer. For ground connection, the second routing circuitry may be further electrically coupled to the metal plate and the optional metal posts. For instance, the second routing circuitry, electrically connected to the first routing circuitry by bonding wires, may include metallized vias in the buildup insulating layer that are formed in contact with the optional metal posts of the heat spreader. As an alternative, the optional metal posts may extend through the second routing circuitry and are electrically connected to the first routing circuitry of the sub-assembly by bonding wires. Accordingly, the metal plate and the optional metal posts can be electrically coupled to the first routing circuitry. Additionally, the outmost conductive traces of the second routing circuitry can accommodate conductive joints, such as solder balls, for electrical communication and mechanical attachment with for the next level assembly or another electronic device.

The bonding wires provide electrical connections between the first routing circuitry of the sub-assembly and the second routing circuitry of the heat spreader. In a preferred embodiment, the bonding wires contact and are attached to the second surface of the first routing circuitry exposed from the through opening of the second routing circuitry and the outer surface of the second routing circuitry facing away from the metal plate. As a result, the first and second devices can be electrically connected to the second routing circuitry for external connection through the first routing circuitry and the bonding wires.

The term “cover” refers to incomplete or complete coverage in a vertical and/or lateral direction. For instance, in a preferred embodiment, the thermally conductive plate covers the first device in the first direction regardless of whether another element such as the thermally conductive adhesive is between the first device and the thermally conductive plate.

The phrases “attached to”, “attached on” and “mounted on” includes contact and non-contact with a single or multiple element(s). For instance, in a preferred embodiment, the peripheral edges of the face-to-face semiconductor sub-assembly are attached to the interior sidewalls of the through opening and the aperture of the heat spreader regardless of whether the peripheral edges of the sub-assembly are separated from the interior sidewalls of the heat spreader by the adhesive or the encapsulant.

The phrases “electrical connection”, “electrically connected” and “electrically coupled” refer to direct and indirect electrical connection. For instance, in a preferred embodiment, the bonding wires directly contact and are electrically connected to the second routing circuitry, and the first routing circuitry is spaced from and electrically connected to the second routing circuitry by the bonding wires.

The “first direction” and “second direction” do not depend on the orientation of the semiconductor assembly, as will be readily apparent to those skilled in the art. For instance, the first surface of the first routing circuitry faces the first direction and the second surface of the first routing circuitry faces the second direction regardless of whether the semiconductor assembly is inverted. Thus, the first and second directions are opposite one another and orthogonal to the lateral directions. Furthermore, the first direction is the upward direction and the second direction is the downward direction when the outer surface of the second routing circuitry faces in the downward direction, and the first direction is the downward direction and the second direction is the upward direction when the outer surface of the second routing circuitry faces in the upward direction.

The semiconductor assembly according to the present invention has numerous advantages. For instance, the first and second devices are mounted on opposite sides of the first routing circuitry, which can offer the shortest interconnect distance between the first and second devices. The first routing circuitry provides primary fan-out routing/interconnection for the first and second devices, whereas the second routing circuitry provides a second level fan-out routing/interconnection. As the first routing circuitry of the sub-assembly are connected to the second routing circuitry of the heat spreader by bonding wires, not by direct build-up process, the simplified process steps result in lower manufacturing cost. The heat spreader can provide thermal dissipation, electromagnetic shielding and moisture barrier for the first device, and also provides mechanical support for the assembly. The semiconductor assembly made by this method is reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A thermally enhanced semiconductor assembly with three dimensional integration, comprising:
a face-to-face semiconductor sub-assembly that includes a first device, a second device and a first routing circuitry, wherein the first device is electrically coupled to a first surface of the first routing circuitry and the second device is electrically coupled to a second surface of the first routing circuitry opposite to the first surface;
a heat spreader that includes a metal plate and a second routing circuitry disposed over a surface of the metal plate, wherein the second routing circuitry has a through opening and the face-to-face semiconductor sub-assembly is disposed in the through opening with the first device attached to the heat spreader and the second surface of the first routing circuitry facing in the same direction as an outer surface of the second routing circuitry; and
a plurality of bonding wires that electrically couple the face-to-face semiconductor sub-assembly to the heat spreader through the first routing circuitry and the second routing circuitry.

2. The semiconductor assembly of claim 1, wherein the heat spreader further includes a metal post projecting directly from the surface of the metal plate.

3. The semiconductor assembly of claim 1, wherein the metal plate has a recess or an aperture aligned with the through opening of the second routing circuitry.

4. The semiconductor assembly of claim 1, further comprising a molding compound that surrounds the first device and covers the first surface of the first routing circuitry.

5. The semiconductor assembly of claim 1, further comprising an encapsulant that covers the bonding wires.

6. The semiconductor assembly of claim 1, wherein the first device is a semiconductor chip and the second device is a semiconductor chip, a packaged device or a passive component.

7. A method of making a thermally enhanced semiconductor assembly with three dimensional integration, comprising:
providing a face-to-face semiconductor sub-assembly that includes a first device, a second device and a first routing circuitry, wherein the first device is electrically coupled to a first surface of the first routing circuitry and the second device is electrically coupled to a second surface of the first routing circuitry opposite to the first surface;
providing a heat spreader that includes a metal plate and a second routing circuitry, wherein the second routing circuitry is disposed over a surface of the metal plate and has a through opening;
attaching the face-to-face semiconductor sub-assembly in the through opening of the second routing circuitry; and
providing a plurality of bonding wires that electrically couple the face-to-face semiconductor sub-assembly and the heat spreader.

8. The method of claim 7, further comprising a step of providing an encapsulant that covers the bonding wires.
